(19) United States
(12) Patent Application Publication
(10) Pub. No.: US 2026/0281358 A1
(43) Pub. Date: Sep. 17, 2026

(54) Methods and Apparatus of Adaptive Probability Range for Context Models of Context Adaptive Binary Arithmetic Coding in Video Coding

(71) Applicant: MEDIATEK INC., Hsinchu City (TW)

(72) Inventors: Yi-Wen CHEN, San Jose, CA (US); Tzu-Der CHUANG, Hsinchu City (TW); Ching-Yeh CHEN, Hsinchu City (TW); Chih-Wei HSU, Hsinchu City (TW)

(21) Appl. No.: 19/472,648

(22) PCT Filed: Jun. 3, 2024
(86) PCT No.: PCT/CN2024/097006

§ 371 Date: Oct. 4, 2025

Related U.S. Application Data
(60) Provisional application No. 63/506,197, filed on Jun. 5, 2023.

(51) Int. Cl. H04N 19/13; H04N 19/176; H04N 19/91

(52) U.S. Cl. CPC H04N 19/13; H04N 19/176; H04N 19/91

(57) ABSTRACT

A method and apparatus for modifying initial probability range for context modelling associated with CABAC. According to this method, input data of a current block corresponding to binarized bits or binary codewords are received. A modified probability range is generated by clipping a beginning probability or both the beginning probability and an ending probability associated with an initial probability range for context modelling of the CABAC encoder or the CABAC decoder, where the modified probability range excludes a probability value of 0. The current block is encoded using the CABAC encoder according to the modified probability range or the current block is decoded using the CABAC decoder according to the modified probability range.

### CROSS REFERENCE TO RELATED APPLICATIONS

The present invention is a non-Provisional application of and claims priority to U.S. Provisional Patent Application No. 63/506,197, filed on Jun. 5, 2023. The U.S. Provisional patent application is hereby incorporated by reference in its entirety.

### FIELD OF THE INVENTION

The present invention relates to CABAC (Context-Adaptive Binary Arithmetic Coding) of syntax elements in a video coding system. In particular, the present invention relates to modifying an initial probability range associated with the context modelling for CABAC in a video coding system.

### BACKGROUND

Versatile video coding (VVC) is the latest international video coding standard developed by the Joint Video Experts Team (JVET) of the ITU-T Video Coding Experts Group (VCEG) and the ISO/IEC Moving Picture Experts Group (MPEG). The standard has been published as an ISO standard: ISO/IEC 23090-3:2021, Information technology—Coded representation of immersive media—Part 3: Versatile video coding, published February 2021. VVC is developed based on its predecessor HEVC (High Efficiency Video Coding) by adding more coding tools to improve coding efficiency and also to handle various types of video sources including 3-dimensional (3D) video signals.

FIG. 1A illustrates an exemplary adaptive Inter/Intra video encoding system incorporating loop processing. For Intra Prediction 110, the prediction data is derived based on previously coded video data in the current picture. For Inter Prediction 112, Motion Estimation (ME) is performed at the encoder side and Motion Compensation (MC) is performed based on the result of ME to provide prediction data derived from other picture(s) and motion data. Switch 114 selects Intra Prediction 110 or Inter Prediction 112 and the selected prediction data is supplied to Adder 116 to form prediction errors, also called residues. The prediction error is then processed by Transform (T) 118 followed by Quantization (Q) 120. The transformed and quantized residues are then coded by Entropy Encoder 122 to be included in a video bitstream corresponding to the compressed video data. The bitstream associated with the transform coefficients is then packed with side information such as motion and coding modes associated with Intra prediction and Inter prediction, and other information such as parameters associated with loop filters applied to underlying image area. The side information associated with Intra Prediction 110, Inter prediction 112 and in-loop filter 130, is provided to Entropy Encoder 122 as shown in FIG. 1A. When an Inter-prediction mode is used, a reference picture or pictures have to be reconstructed at the encoder end as well. Consequently, the transformed and quantized residues are processed by Inverse Quantization (IQ) 124 and Inverse Transformation (IT) 126 to recover the residues. The residues are then added back to prediction data 136 at Reconstruction (REC) 128 to reconstruct video data. The reconstructed video data may be stored in Reference Picture Buffer 134 and used for prediction of other frames.

As shown in FIG. 1A, incoming video data undergoes a series of processing in the encoding system. The reconstructed video data from REC 128 may be subject to various impairments due to a series of processing. Accordingly, in-loop filter 130 is often applied to the reconstructed video data before the reconstructed video data are stored in the Reference Picture Buffer 134 in order to improve video quality. For example, deblocking filter (DF), Sample Adaptive Offset (SAO) and Adaptive Loop Filter (ALF) may be used. The loop filter information may need to be incorporated in the bitstream so that a decoder can properly recover the required information. Therefore, loop filter information is also provided to Entropy Encoder 122 for incorporation into the bitstream. In FIG. 1A, Loop filter 130 is applied to the reconstructed video before the reconstructed samples are stored in the reference picture buffer 134. The system in FIG. 1A is intended to illustrate an exemplary structure of a typical video encoder. It may correspond to the High Efficiency Video Coding (HEVC) system, VP8, VP9, H.264 or VVC.

The decoder, as shown in FIG. 1B, can use similar or portion of the same functional blocks as the encoder except for Transform 118 and Quantization 120 since the decoder only needs Inverse Quantization 124 and Inverse Transform 126. Instead of Entropy Encoder 122, the decoder uses an Entropy Decoder 140 to decode the video bitstream into quantized transform coefficients and needed coding information (e.g. ILPF information, Intra prediction information and Inter prediction information). The Intra prediction 150 at the decoder side does not need to perform the mode search. Instead, the decoder only needs to generate Intra prediction according to Intra prediction information received from the Entropy Decoder 140. Furthermore, for Inter prediction, the decoder only needs to perform motion compensation (MC 152) according to Inter prediction information received from the Entropy Decoder 140 without the need for motion estimation.

### Partitioning of the CTUs Using a Tree Structure

In HEVC, a CTU is split into CUs by using a quaternary-tree (QT) structure denoted as coding tree to adapt to various local characteristics. The decision whether to code a picture area using inter-picture (temporal) or intra-picture (spatial) prediction is made at the leaf CU level. Each leaf CU can be further split into one, two or four Pus according to the PU splitting type. Inside one PU, the same prediction process is applied and the relevant information is transmitted to the decoder on a PU basis. After obtaining the residual block by applying the prediction process based on the PU splitting type, a leaf CU can be partitioned into transform units (TUs) according to another quaternary-tree structure similar to the coding tree for the CU. One of key feature of the HEVC structure is that it has the multiple partition conceptions including CU, PU, and TU.

In VVC, a quadtree with nested multi-type tree using binary and ternary splits segmentation structure replaces the concepts of multiple partition unit types, i.e. it removes the separation of the CU, PU and TU concepts except as needed for CUs that have a size too large for the maximum transform length, and supports more flexibility for CU partition shapes. In the coding tree structure, a CU can have either a square or rectangular shape. A coding tree unit (CTU) is first partitioned by a quaternary tree (a.k.a. quadtree) structure. Then the quaternary tree leaf nodes can be further partitioned by a multi-type tree structure. As shown in FIG. 2, there are four splitting types in multi-type tree structure, vertical binary splitting (SPLIT_BT_VER 210), horizontal binary splitting (SPLIT_BT_HOR 220), vertical ternary splitting (SPLIT_TT_VER 230), and horizontal ternary splitting (SPLIT_TT_HOR 240). The multi-type tree leaf nodes are called coding units (CUs), and unless the CU is too large for the maximum transform length, this segmentation is used for prediction and transform processing without any further partitioning. This means that, in most cases, the CU, PU and TU have the same block size in the quadtree with nested multi-type tree coding block structure. The exception occurs when maximum supported transform length is smaller than the width or height of the colour component of the CU.

FIG. 3 shows a CTU divided into multiple CUs with a quadtree and nested multi-type tree coding block structure, where the bold block edges represent quadtree partitioning and the remaining edges represent multi-type tree partitioning. The quadtree with nested multi-type tree partition provides a content-adaptive coding tree structure comprised of CUs. The size of the CU may be as large as the CTU or as small as 4×4 in units of luma samples. For the case of the 4:2:0 chroma format, the maximum chroma CB size is 64/64 and the minimum size chroma CB consist of 16 chroma samples.

In VVC, the maximum supported luma transform size is 64×64 and the maximum supported chroma transform size is 32×32. When the width or height of the CB is larger the maximum transform width or height, the CB is automatically split in the horizontal and/or vertical direction to meet the transform size restriction in that direction.

In VVC, the coding tree scheme supports the ability for the luma and chroma to have separate block tree structures. For P and B slices, the luma and chroma CTBs in one CTU have to share the same coding tree structure. However, for I slices, the luma and chroma can bave separate block tree structures. When the separate block tree mode is applied, luma CTB is partitioned into CUs by one coding tree structure, and the chroma CTBs are partitioned into chroma CUs by another coding tree structure. This means that a CU in an I slice may consist of a coding block of the luma component or coding blocks of two chroma components, and a CU in a P or B slice always consists of coding blocks of all three colour components unless the video is monochrome.

For each inter-predicted CU, motion parameters consisting of motion vectors, reference picture indices and reference picture list usage index, and additional information needed for the new coding feature of VVC to be used for inter-predicted sample generation. The motion parameter can be signalled in an explicit or implicit manner. When a CU is coded with skip mode, the CU is associated with one PU and has no significant residual coefficients, no coded motion vector delta or reference picture index. A merge mode is specified whereby the motion parameters for the current CU are obtained from neighbouring CUs, including spatial and temporal candidates, and additional candidates introduced in VVC. The merge mode can be applied to any inter-predicted CU, not only for skip mode. The alternative to merge mode is the explicit transmission of motion parameters, where motion vector, corresponding reference picture index for each reference picture list, reference picture list usage flag and other needed information are signalled explicitly per each CU.

ITU-T VCEG (Q6/16) and ISO/IEC MPEG (JTC 1/SC 29/WG 5) are studying the potential need for standardization of future video coding technology with a compression capability significantly exceeding that of the current VVC standard. The Enhanced Compression Model (ECM) reference software is provided to demonstrate a reference implementation of encoding techniques and the decoding process for JVET enhanced compression beyond VVC capability exploration work. The reference software can be accessed via:
https://vegit.bhi.fraunhofer.de/ecm/ECM.git. E
http://phenix.int-evry.fr/jet/doc_end_user/documents/12_Geneva/wg11/JCTVC-L1002-v3.zip
https://www.itu.int/rec/T-REC-H.266-202204-I
https://jvet-experts.org/doc_end_user/documents/19_Teleconference/wg11/JVET-S2002-v2.zip

CM basically is the successor to VVC and thus it shares many common parts as VVC.

The following text provides the details on some Context-Adaptive Binary Arithmetic Coding (CABAC) related methods specified in HEVC, VVC and ECM.

### Fundamental Concept of CABAC

CABAC is a lossless entropy coding technique used in video compression standards such as H.264/AVC, H.265/HEVC, H.266/VVC and ECM. It is used to compress the syntax elements of video data, which represent various parameters used to encode the video, such as motion vectors, quantization parameters, and prediction modes.

As illustrated in FIGS. 4A-B, CABAC works by assigning binary codewords to each syntax element, with more probable syntax elements assigned shorter codewords. The probability of a CABAC context model represents the likelihood of a particular symbol (0 or 1) occurring in a particular context. The probability is a value between 0 and 1, and it is usually represented using a fixed-point arithmetic notation. The probability of a particular syntax element is estimated based on the context of the element, which includes the neighbouring syntax elements and the previously coded syntax elements. The context is used to determine the likelihood of a particular value for the syntax element.

The probability estimates are updated dynamically as each syntax element is coded, allowing the coding to adapt to the statistical properties of the video data. This adaptive context modelling is a key feature of CABAC, as it allows for more accurate probability estimates and improved compression efficiency.

The binary codewords for each syntax element are generated using binary arithmetic coding, which is a technique for encoding data using a series of binary digits. Binary arithmetic coding is a more efficient method of encoding data than fixed-length coding, as it can generate codewords of varying length depending on the probability of the syntax element.

The initial probabilities for different context models in CABAC can be different, based on the characteristics of the syntax elements being encoded. The initial probability estimates for each context model can be initialized to specific values. In general, the most effective initial probability estimates for each context model are determined through an iterative training process that involves encoding sample video data and measuring the compression efficiency and video quality achieved. In the existing video coding standards including H.264/AVC, H.265/HEVC, H.266/VVC and ECM, the initial probabilities for all the CABAC context models are pre-trained and specified in the specifications of the corresponding video coding standards. A CABAC encoder 410 is shown in FIG. 4A, where the input syntax element is converted to a binary string by using Binarization unit 412. At the same time, the syntax element is also provided to Context Modelling unit 414 for adaptively updating the model. Side information relate to the context model is also provided to Context Modelling unit 414. The binary codewords for each syntax element are generated using Binary Arithmetic Coding unit 416. FIG. 4B illustrates an example of CABAC decoder 420, which comprises Context Modelling unit 422, DeBinarization unit 424 and Context Modelling unit 426.

In summary, CABAC is an important component of video compression standards, as it provides efficient compression of the video data while maintaining lossless quality. Its adaptive context modelling and binary arithmetic coding techniques allow for more accurate probability estimates and improved compression efficiency, leading to higher-quality video with reduced bit rates.

### CABAC in H.265/HEVC

To achieve multiplication-free binary arithmetic coding scheme, H.265/HEVC relies on the assumption that the estimated probabilities of each context model can be represented by a sufficiently limited set of representative values. In H.265/HEVC, each probability model related to a given context index is determined by a pair of two values, a 6-bit probability state index and the (binary) value of the most probable symbol (MPS), hence the models themselves can be efficiently represented by 7-bit unsigned integer values. As a result of this design, each context model in CABAC can be completely determined by two parameters: its current estimate of the low-probability symbol (LPS) probability, which in turn is characterized by an index between 0 and 63, and its value of being either 0 or 1. Thus, probability estimation in CABAC is performed by using a total number of 128 different probability states, each of them efficiently represented by a 7-bit integer value.

For a given probability state, the update depends on the state index and the value of the encoded symbol identified either as a LPS or a most-probability symbol (MPS). As a result of the updating process, a new probability state is derived, which consists of a potentially modified LPS probability estimate and, if necessary, a modified MPS value. FIG. 5 illustrates the probability values for the LPS estimates together with their corresponding transition rules for updating the state indices. In the event of a MPS, a given state index is simply incremented by 1, unless a MPS occurs at state index 62, where the LPS probability is already at its minimum, or equivalently, the maximum MPS probability is reached. In the latter case, the state index 62 remains fixed until a LPS is seen, in which case the state index is changed by decrementing the state index by an amount illustrated by the dashed line in FIG. 5.

The CABAC engine in HEVC uses a table-based probability transition process between 64 different representative probability states. In HEVC, the range ivlCurrRange representing the state of the coding engine is quantized to a set of 4 values prior to the calculation of the new interval range. The HEVC state transition can be implemented using a table containing all 64×4 8-bit pre-computed values to approximate the values of ivlCunRange*pLPS (pStateIdx), where pLPS is the probability of the least probable symbol (LPS) and pStateIdx is the index of the current state. Also, a decode decision can be implemented using the pre-computed LUT. First ivILpsRange is obtained using the LUT as follows. Then, ivILpsRange is used to update iv/CurrRange and calculate the output bin Val.

ivILpsRange=rangeTabLps[pStateIdx][qRangeldx].

### CABAC in VVC

CABAC is also used in Versatile Video Coding (VVC), which is the successor to HEVC. However, the CABAC used in VVC has some differences compared to the one used in HEVC.

In VVC, CABAC is designed to be more efficient and to support a wider range of bit depths and chroma sampling formats. One of the main improvements in CABAC in VVC is the use of more flexible and efficient context modelling techniques, which allow for more accurate probability estimates and improved compression efficiency.

VVC also introduces a new adaptive scanning order for CABAC, which is designed to improve the efficiency of the binary arithmetic coding process. This new scanning order is optimized for the distribution of syntax elements in VVC, and it allows for faster and more accurate probability estimation.

Another key difference in CABAC in VVC is the use of a new bypass mode, which allows for direct mapping of syntax elements to binary codewords without the need for probability estimation. This can improve coding efficiency for syntax elements that have a high probability of occurrence.

Overall, CABAC in VVC is designed to be more efficient and flexible than the one used in HEVC, which helps to improve compression efficiency and reduce bit rates for high-quality video content.

In VVC, the probability is linearly expressed by the probability index pStateIdx. Therefore, all the calculation can be done with equations without LUT operation. To improve the accuracy of probability estimation, a multi-hypothesis probability update model is applied. The pStateIdx used in the interval subdivision in the binary arithmetic coder is a combination of two probabilities pStateIdx0 and pStateIdx1. The two probabilities are associated with each context model and are updated independently with different adaptation rates. The adaptation rates of pStateIdx0 and pStateIdx1 for each context model are pre-trained based on the statistics of the associated bins. The probability estimate pStateIdx is the average of the estimates from the two hypotheses.

FIG. 6 shows the flowchart for decoding a single binary decision in VVC. As shown FIG. 6, the flowchart starts with function call, DecodeDecision (ctxTable, etxIdx) 610. In step 620, a set of operations related interval range is performed. In step 630, the offset to the initial probability of the context model (i.e., ivlOffset) is compared with the interval range (i.e., ivlCurRange). If ivlOffset is greater than or equal to ivlCurrRange, step 640 is performed. Otherwise step 650 is performed. In step 640, the decoded bin value (bin Val) is set to lvalMps and the ivlCunRange is adjusted. In step 650, the decoded bin value (binVal) is set to valMps. In step 660, a short and a long window size (i.e., shift0 and shift1) and the index of the current state (i.e., pStateIdx0 and pStateIdx1) are updated. In step 670, the interval range is remormalized. As done in HEVC, CABAC for VVC also has a QP dependent initialization process invoked at the beginning of each slice. Given the initial value of luma QP for the slice, the initial probability state of a context model, denoted as preCtxState, is derived as follows:

$$m = slopeIdx \times 5 - 45 ,$$

$$n = ( offsetIdx ≪ 3 ) + 7 , and$$

$$preCtxState = Clip 3 ( 1 , 127 , ( ( m \times ( QP - 32 ) ) ≫ 4 ) + n ) .$$

where slopeIdx and offsetIdx are restricted to 3 bits, and total initialization values are represented by 6-bit precision. The probability state preCtxState represents the probability in the linear domain directly. Hence, preCtxState only needs proper shifting operations before input to arithmetic coding engine, and the logarithmic to linear domain mapping as well as the 256-byte table is saved.

$$pStateIdx 0 = preCtxState ≪ 3$$

$$pStateIdx 1 = preCtxState ≪ 7$$

### CABAC in ECM

### Extended Precision

The intermediate precision used in the arithmetic coding engine is increased, including three elements. First, the precisions for two probability states are both increased to 15 bits, in comparison to 10 bits and 14 bits in VVC. Second, the LPS range update process is modified as below:

$$if q >= 16384$$

$$q = {2}^{15} - 1 - q$$

$${R}_{LPS} = ( ( range * ( q ≫ 6 ) ) ≫ 9 ) + 1 ,$$

where range is a 9-bit variable representing the width of the current interval, q is a 15-bit variable representing the probability state of the current context model, and R_{LPS} is the updated range for LPS. This operation can also be realized by looking up a 512×256-entry in 9-bit look-up table. Third, at the encoder side, the 256-entry look-up table used for bits estimation in VTM is extended to 512 entries.

### Slice-Type-Based Window Size

Since statistics are different with different slice types, it is beneficial to have a context's probability state updated at a rate that is optimal under the given slice type. Therefore, for each context model, three window sizes are pre-defined for I-, B-, and P-slices, respectively, like the initialization parameters.

The context initialization parameters and window sizes are retrained.

Multi-Hypothesis Probability Estimation with Adaptive Weight

The multi-hypothesis-based probability is estimated based on adaptive weights (MHP-AW). Specifically, two separate probability estimates p₀ and p₁ are maintained for each context and updated according to their own adaptation rates. However, instead of using simple average, multiple weights are introduced to derive the resulting probability p used for the binary arithmetic coding, as illustrated as follows:

$$p = ( {ω}_{0} \cdot {p}_{0} + {ω}_{1} \cdot {p}_{1} ) ≫ s ,$$

where ω₀ and ω₁ are the weights selected from a pre-defined set {10, 12, 16, 20, 22}; s is the bitwise right-shift value, which is equal to 5 when (ω₀+ω₁)≤32 and 6 otherwise. Three different sets of weights are pre-determined for each context model at I-, B- and P-slice types. The weights of I-slice type are only allowed for intra slices while the weights of B- and P-slice types are allowed to be switched for inter slices at slice level.
CABAC Initialization from Previous Inter Slice and Windows Adjustment

Context initialization stored at previously coded picture after coding the last CTU can be used to initialize an inter slice having the same slice type, QP, and temporal ID. The buffer size for storing previous initializations is set equal to 5 for each slice type, when the buffer is full, the entry with the smallest QP and temporal ID is removed first before storing the initialization.

The CABAC employs two probability states that are updated with a short and a long window size, respectively. The window sizes, predefined for each context model, are not optimal for varying statistics in different regions, hence window sizes are adjusted according to the previously coded bin of each context.

The short and long window sizes used in CABAC update are adjusted by two delta parameters stored in a look-up table per context and retrieved by a previous coded bin used as an index. The previous coded bin is used as an index to get the adjustment parameters from a look-up table: delta0 for the short window and delta1 for the long window. Denote the original short and long window sizes stored in the existed initialization tables and defined for the context model as shift0 and shift1, respectively. The actual window sizes used to code the current bin after adjustment are (shift0+delta0) and (shift1+delta1), where shift0 and shift1 are existing predefined windows sizes stored in the context initialization tables.

In the present invention, methods and apparatus to modify the initial probability range for context modelling of CABAC encoder or decoder. In particular, the beginning probability or both the beginning probability and ending probability are modified so that to improve the coding efficiency for CABAC.

### BRIEF SUMMARY OF THE INVENTION

A method and apparatus for modifying initial probability range for context modelling associated with CABAC are disclosed. According to this method, input data related to a current block are received, wherein the input data correspond to binarized bits corresponding to one or more syntax elements of the current block to be encoded using a CABAC encoder at a video encoder side, or the input data correspond to binary codewords for said one or more syntax elements of the current block generated by the CABAC encoder and to be decoded using a CABAC decoder at a video decoder side. A modified probability range is generated by clipping a probability range for context modelling of the CABAC encoder or the CABAC decoder, wherein the modified probability range excludes a probability value of 0. The current block is encoded using the CABAC encoder according to the modified probability range or the current block is decoded using the CABAC decoder according to the modified probability range.

In one embodiment, the modified probability range is generated by clipping a beginning probability or both the beginning probability and an ending probability associated with an initial probability range for the context modelling of the CABAC encoder or the CABAC decoder. In one embodiment, a minimum probability is used to clip the beginning probability, or both the minimum probability and a maximum probability are used to clip both the beginning probability and the ending probability. In one embodiment, the minimum probability is represented by a first index, or both the minimum probability and the maximum probability are represented by the first index and a second index respectively. In one embodiment, when 15 bits are used to represent indexes for corresponding probabilities in the initial probability range, the first index corresponds to 16, or the first index and the second index correspond to 16 and (32767-16) respectively.

In one embodiment, the first index or both the first index and the second index are both predefined. In another embodiment, the first index or the first index and the second index are signalled in or parsed from one or more bitstream levels. In one embodiment, said one or more bitstream levels comprise video level, sequence level, picture level, slice level, block level, or a combination thereof.

In one embodiment, the minimum probability or the maximum probability is selected from a set of predefined values. In one embodiment, the minimum probability or the maximum probability is selected from the set of predefined values by using an index.

In one embodiment, the minimum probability is determined by subtracting an offset value from or adding the offset to the beginning probability associated with the initial probability range. In one embodiment, the offset value corresponds to a non-negative number.

In one embodiment, part or all of coded or parsed bins for each context model or part of context models are stored for generating a further modified probability range according to a modified minimum probability or both the modified minimum probability and modified maximum probability derived based on stored part or all of coded or parsed bins. In one embodiment, the modified minimum probability or both the modified minimum probability and the modified maximum probability are inherited by other slices, pictures, tiles or any other data being encoded or decoded after a current slice.

In one embodiment, a control syntax element indicating whether to use the modified probability range is signalled in a bitstream or parsed from the bitstream. In one embodiment, the control syntax element is signalled or parsed in video level, sequence level, picture level, slice level, block level, or a combination thereof.

### BRIEF DESCRIPTION OF THE DRAWINGS

FIG. 1A illustrates an exemplary adaptive Inter/Intra video coding system incorporating loop processing.

FIG. 1B illustrates a corresponding decoder for the encoder in FIG. 1A.

FIG. 2 illustrates an example of multi-type tree splitting modes.

FIG. 3 illustrates an example of quadtree with nested multi-type tree coding block structure.

FIG. 4A illustrates an example of CABAC encoder.

FIG. 4B illustrates an example of CABAC decoder.

FIG. 5 illustrates an example of CABAC probability transition rules.

FIG. 6 illustrates an exemplary flowchart of CABSC decoder for decoding a bin.

FIG. 7 illustrates a flowchart of an exemplary video coding system that uses a modified probability range for context modelling used by a CABAC encoder or decoder according to an embodiment of the present invention.

### DETAILED DESCRIPTION OF THE INVENTION

It will be readily understood that the components of the present invention, as generally described and illustrated in the figures herein, may be arranged and designed in a wide variety of different configurations. Thus, the following more detailed description of the embodiments of the systems and methods of the present invention, as represented in the figures, is not intended to limit the scope of the invention, as claimed, but is merely representative of selected embodiments of the invention. References throughout this specification to “one embodiment,” “an embodiment,” or similar language mean that a particular feature, structure, or characteristic described in connection with the embodiment may be included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. One skilled in the relevant art will recognize, however, that the invention can be practiced without one or more of the specific details, or with other methods, components, etc. In other instances, well-known structures, or operations are not shown or described in detail to avoid obscuring aspects of the invention. The illustrated embodiments of the invention will be best understood by reference to the drawings, wherein like parts are designated by like numerals throughout. The following description is intended only by way of example, and simply illustrates certain selected embodiments of apparatus and methods that are consistent with the invention as claimed herein.

In ECM, the probability of a CABAC context model is represented by 15 bits (the largest integer number represented by 15 bits is 32767) and thus the probability ranges from 0 to 32767/32768. The granularity of the probability representation is 1/32768 and there are 2¹⁵ probability states to represent the probability of the CABAC context model. The probability of each CABAC context model ranges from 0 to 32767/32768 which equally ranges from 0 to 99.9969% with index granularity 1/32768 (which is 0.003%). The issue here is that the probability context model may not need extremely low and/or high probability (e.g. <1% or >99%).

In this invention, it is proposed to clip the range of the probability of a CABAC model within a predefined range.

In the first embodiment of this invention, a minimum probability and a maximum probability are used to clip the range of the probability of all CABAC context models. The minimum and maximum probability can be expressed as an index (or termed as state) of the probability (or a probability value). In one example that utilizes the ECM CABAC probability representation, the minimum probability is index 16 while the maximum probability is index 32767-16 (which is 32751). The index (or termed as state) of the minimum and maximum probability can then be predefined at the encoder and decoder. Alternatively, the index (or termed as state) of the minimum and maximum probability can then be signalled in the bitstream at different levels such as video level (e.g. video parameters set, VPS), sequence level (e.g. sequence parameter set, SPS), picture level (e.g. picture parameters set, PPS; picture header), slice level (e.g. slice header), and/or block level (e.g. CTU, CU, CTB, CB).

In the second embodiment of this invention, a minimum probability and a maximum probability are used to clip the range of the probability of one specific CABAC context model. The minimum and maximum probability could be expressed as index (or termed as state) of the probability (or a probability value). In one example which utilizes the ECM CABAC probability representation, the minimum probability is index 16 while the maximum probability is index 32767-16 (which is 32751). The index (or termed as state) of the minimum and maximum probability could then be predefined at the encoder and decoder. Alternatively, the index (or termed as state) of the minimum and maximum probability could then be signaled into the bitstream at different levels such as video level (e.g. video parameters set, VPS), sequence level (e.g. sequence parameter set, SPS), picture level (e.g. picture parameters set, PPS; picture header), slice level (e.g. slice header), and/or block level (e.g. CTU, CU, CTB, CB).

In the third embodiment, a minimum probability and a maximum probability are used to clip the range of the probability of one set of at least one CABAC context models. The minimum and maximum probability could be expressed as index (or termed as state) of the probability (or a probability value). In one example which utilizes the ECM CABAC probability representation, the minimum probability is index 16 while the maximum probability is index 32767-16 (which is 32751). The index (or termed as state) of the minimum and maximum probability could then be predefined at the encoder and decoder. Alternatively, the index (or termed as state) of the minimum and maximum probability could then be signaled into the bitstream at different levels such as video level (e.g. video parameters set, VPS), sequence level (e.g. sequence parameter set, SPS), picture level (e.g. picture parameters set, PPS; picture header), slice level (e.g. slice header), and/or block level (e.g. CTU, CU, CTB, CB). The set of CABAC context models can be CU partition related context set, CU/PU/TU mode related context set, coefficient coding related context set, loop filtering related context set.

In the fourth embodiment, a minimum probability and a maximum probability are used to clip the range of the probability of the CABAC context models. The minimum and maximum probability could be expressed as index (or termed as state) of the probability or a probability value. The minimum and/or maximum probability could be selected as one probability value from a set of predefined probability indices or probability values. For example, a set for minimum probabilities is defined as {16/32768, 32/32768, 64/32768, 128/32768}; the minimum probability is then specified by the index to the minimum probability set. Similarly, a set for maximum probabilities is defined as {32752/32768, 32736/32768, 32720/32768, 32704/32768}; the maximum probability is then specified by the index to the maximum probability set.

In the fifth embodiment, the minimum probability is determined by subtracting an offset to the initial probability of the context model. The offset value could be any non-negative number. For example, if the initial probability of a context model is “8192/32768” and the offset if “4096/32768”, the minimum probability is then determined as “(8192-4096)/32768” which is “4096/32768”.

In the sixth embodiment, the maximum probability is determined by adding an offset to the initial probability of the context model. The offset value could be any non-negative number. For example, if the initial probability of a context model is “8192/32768” and the offset if “4096/32768”, the minimum probability is then determined as “(8192+4096)/32768” which is “12288/32768”.

In the seventh embodiment, part of coded/parsed bins or all of coded/parsed bin for each context model or part of context models can be stored. The encoder and the decoder can calculate the best probability limitation (e.g. best maximum and best minimum probabilities) for each context model or part of context models by using the stored bins. In one example, codec can re-encode the CABAC for one certain context model with the stored bins with different probability limitation and see how many bits are required with this probability limitation. From the result, one best probability limitation can be determined. The information of the best probability limitation can be inherited by other slices/pictures/tiles or any other data that encoded/decoded after the current slice. For example, the best probability limitation can be inherited by the following coded slice with same QP or with same temporal ID. In this embodiment, in one example, each context model can have different probability limitation. In another example, all the context models can have the same probability limitation. In another example, the context models can be classified into one or more sets. Each context model set can be one probability limitation for the context models in this set.

In the eighth embodiment, the syntax element is signalled in the bitstream to indicate the enabling or disabling of the foregoing proposed methods. The syntax element can be signalled in different level such as video level (e.g. video parameters set, VPS), sequence level (e.g. sequence parameter set, SPS), picture level (e.g. picture parameters set, PPS; picture header), slice level (e.g. slice header), and/or block level (e.g. CTU, CU, CTB, CB).

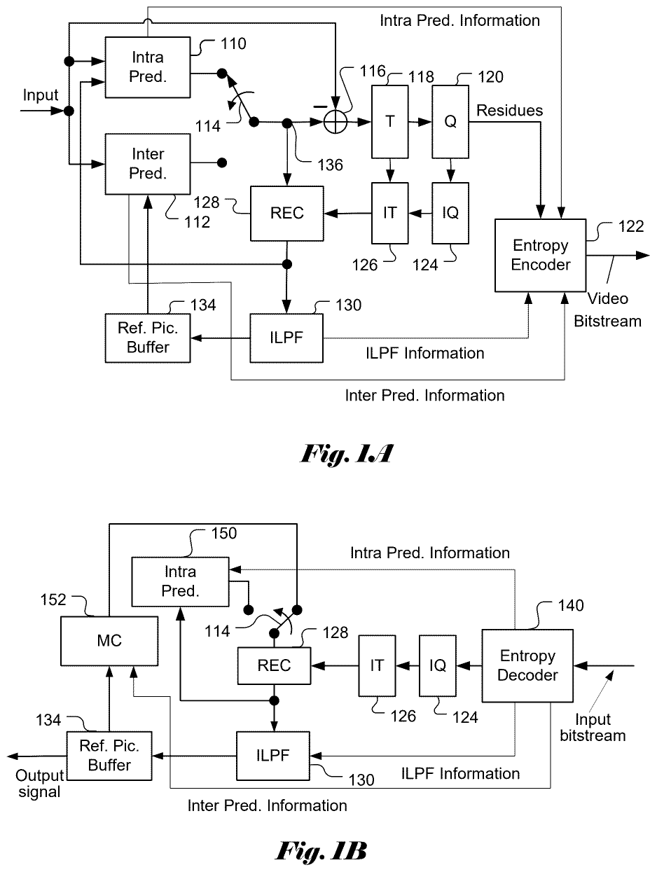

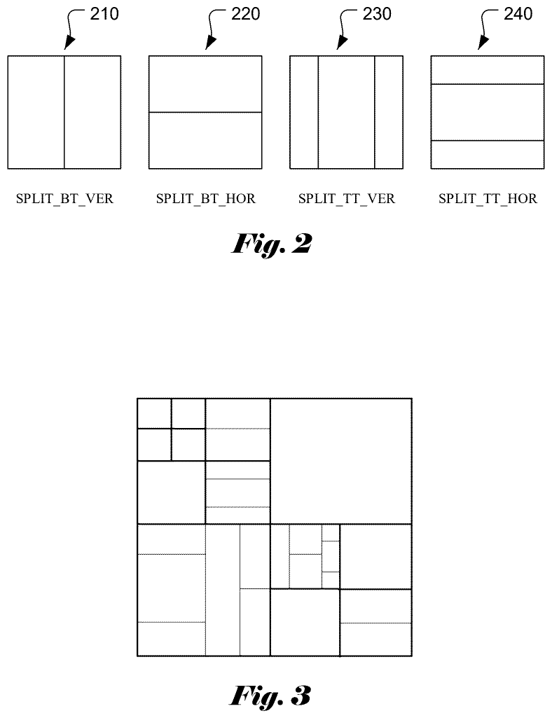

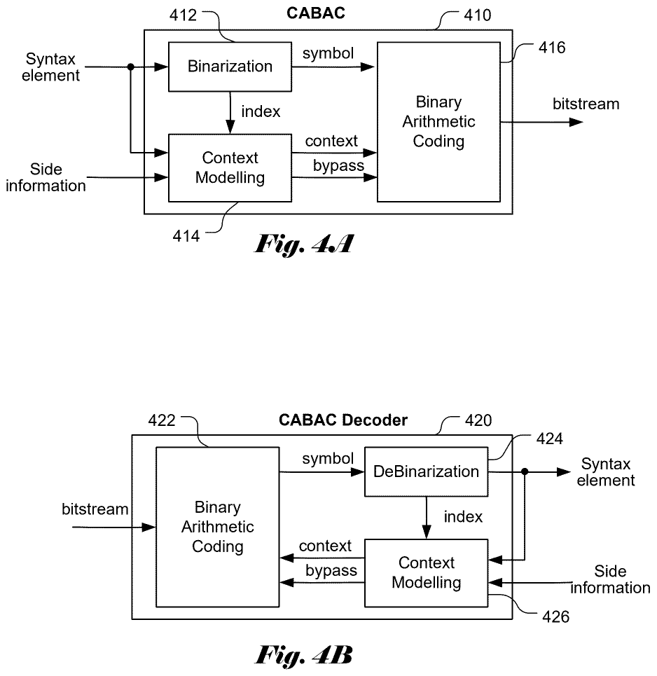

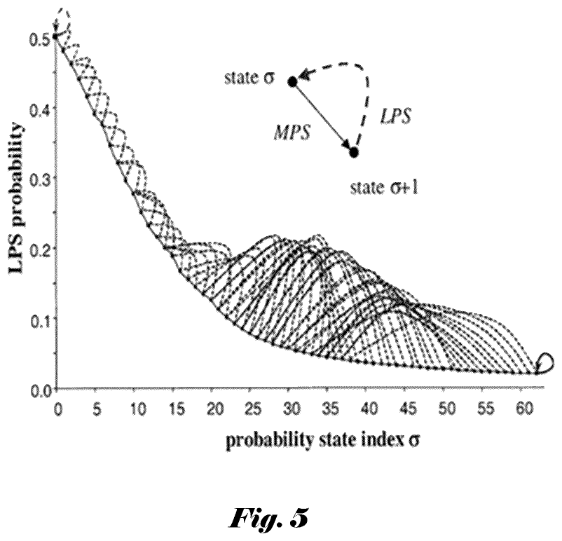

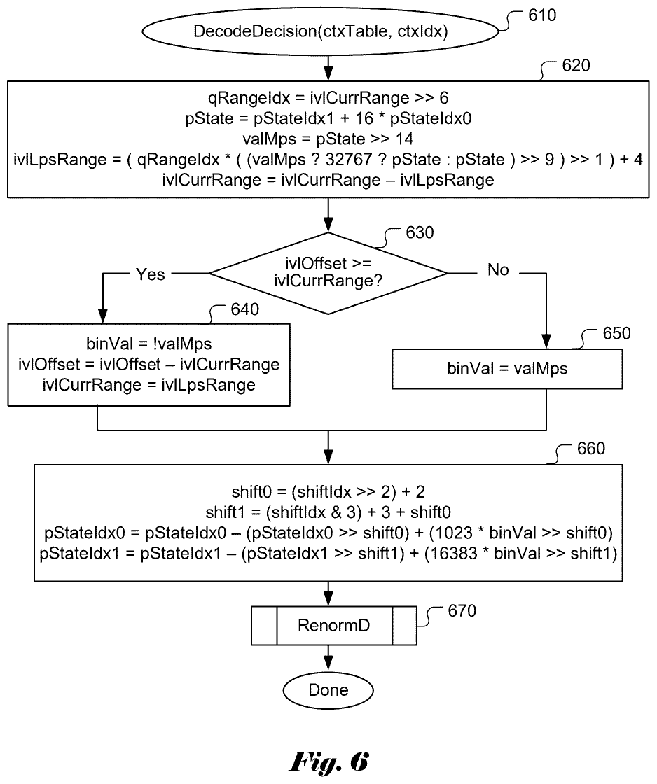

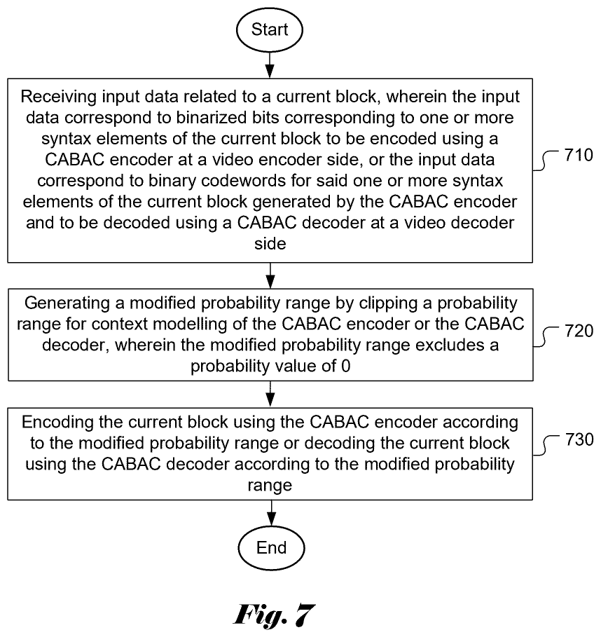

Any of the foregoing proposed CABAC methods can be applied independently or jointly. Moreover, any of the foregoing CABAC proposed methods can be implemented in encoders and/or decoders. For example, any of the proposed CABAC methods can be implemented in entropy coding (e.g. CABAC) module of an encoder and/or a decoder. Alternatively, any of the proposed methods can be implemented as a circuit coupled to entropy coding (e.g. CABAC) module of the encoder and/or the decoder. With respect to the reference video encoder in FIG. 1A and the reference video decoder in FIG. 1B, any of the proposed CABAC methods can be implemented in the Entropy Encoder module 122 in the encoder side or the Entropy Decoder module 140 in the decoder side. The required processing for the present invention may be implemented according to executable software or firmware codes stored on a media, such as hard disk or flash memory, for a CPU (Central Processing Unit) or programmable devices (e.g. DSP (Digital Signal Processor) or FPGA (Field Programmable Gate Array)).

FIG. 7 illustrates a flowchart of an exemplary video coding system that uses a modified probability range for context modelling used by a CABAC encoder or decoder according to an embodiment of the present invention. The steps shown in the flowchart may be implemented as program codes executable on one or more processors (e.g., one or more CPUs) at the encoder side. The steps shown in the flowchart may also be implemented based hardware such as one or more electronic devices or processors arranged to perform the steps in the flowchart. A method and apparatus for modifying initial probability range for context modelling associated with CABAC are disclosed. According to this method, input data related to a current block are received in step 710, wherein the input data correspond to binarized bits corresponding to one or more syntax elements of the current block to be encoded using a CABAC encoder at a video encoder side, or the input data correspond to binary codewords for said one or more syntax elements of the current block generated by the CABAC encoder and to be decoded using a CABAC decoder at a video decoder side. A modified probability range is generated in step 720 by clipping a probability range for context modelling of the CABAC encoder or the CABAC decoder, wherein the modified probability range excludes a probability value of 0. The current block is encoded using the CABAC encoder according to the modified probability range or the current block is decoded using the CABAC decoder according to the modified probability range in step 730.

The flowcharts shown are intended to illustrate an example of video coding according to the present invention. A person skilled in the art may modify each step, re-arranges the steps, split a step, or combine steps to practice the present invention without departing from the spirit of the present invention. In the disclosure, specific syntax and semantics have been used to illustrate examples to implement embodiments of the present invention. A skilled person may practice the present invention by substituting the syntax and semantics with equivalent syntax and semantics without departing from the spirit of the present invention.

The above description is presented to enable a person of ordinary skill in the art to practice the present invention as provided in the context of a particular application and its requirement. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed. In the above detailed description, various specific details are illustrated in order to provide a thorough understanding of the present invention. Nevertheless, it will be understood by those skilled in the art that the present invention may be practiced.

Embodiment of the present invention as described above may be implemented in various hardware, software codes, or a combination of both. For example, an embodiment of the present invention can be one or more circuit circuits integrated into a video compression chip or program code integrated into video compression software to perform the processing described herein. An embodiment of the present invention may also be program code to be executed on a Digital Signal Processor (DSP) to perform the processing described herein. The invention may also involve a number of functions to be performed by a computer processor, a digital signal processor, a microprocessor, or field programmable gate array (FPGA). These processors can be configured to perform particular tasks according to the invention, by executing machine-readable software code or firmware code that defines the particular methods embodied by the invention. The software code or firmware code may be developed in different programming languages and different formats or styles. The software code may also be compiled for different target platforms. However, different code formats, styles and languages of software codes and other means of configuring code to perform the tasks in accordance with the invention will not depart from the spirit and scope of the invention.

The invention may be embodied in other specific forms without departing from its spirit or essential characteristics. The described examples are to be considered in all respects only as illustrative and not restrictive. The scope of the invention is therefore, indicated by the appended claims rather than by the foregoing description. All changes which come within the meaning and range of equivalency of the claims are to be embraced within their scope.

1. A method of video coding, the method comprising:
receiving input data related to a current block, wherein the input data correspond to binarized bits corresponding to one or more syntax elements of the current block to be encoded using a CABAC encoder at a video encoder side, or the input data correspond to binary codewords for said one or more syntax elements of the current block generated by the CABAC encoder and to be decoded using a CABAC decoder at a video decoder side;
generating a modified probability range by clipping a probability range for context modelling of the CABAC encoder or the CABAC decoder, wherein the modified probability range excludes a probability value of 0; and
encoding the current block using the CABAC encoder according to the modified probability range or decoding the current block using the CABAC decoder according to the modified probability range.

2. The method of claim 1, wherein the modified probability range is generated by clipping a beginning probability or both the beginning probability and an ending probability associated with an initial probability range for the context modelling of the CABAC encoder or the CABAC decoder.

3. The method of claim 2, wherein a minimum probability is used to clip the beginning probability, or both the minimum probability and a maximum probability are used to clip both the beginning probability and the ending probability.

4. The method of claim 3, wherein the minimum probability is represented by a first index, or both the minimum probability and the maximum probability are represented by the first index and a second index respectively.

5. The method of claim 4, wherein when 15 bits are used to represent indexes for corresponding probabilities in the initial probability range, the first index corresponds to 16, or the first index and the second index correspond to 16 and (32767-16) respectively.

6. The method of claim 4, wherein the first index or both the first index and the second index are both predefined.

7. The method of claim 4, wherein the first index or the first index and the second index are signalled in or parsed from one or more bitstream levels.

8. The method of claim 7, wherein said one or more bitstream levels comprise video level, sequence level, picture level, slice level, block level, or a combination thereof.

9. The method of claim 3, wherein the minimum probability or the maximum probability is selected from a set of predefined values.

10. The method of claim 9, wherein the minimum probability or the maximum probability is selected from the set of predefined values by using an index.

11. The method of claim 3, wherein the minimum probability is determined by subtracting an offset value from or adding the offset to the beginning probability associated with the initial probability range.

12. The method of claim 11, wherein the offset value corresponds to a non-negative number.

13. The method of claim 1, wherein part or all of coded or parsed bins for each context model or part of context models are stored for generating a further modified probability range according to a modified minimum probability or both the modified minimum probability and modified maximum probability derived based on stored part or all of coded or parsed bins.

14. The method of claim 13, wherein the further modified probability range is used by the CABAC encoder for re-encoding the current block.

15. The method of claim 13, wherein the modified minimum probability or both the modified minimum probability and the modified maximum probability are inherited by other slices, pictures, tiles or any other data being encoded or decoded after a current slice.

16. The method of claim 1, wherein a control syntax element indicating whether to use the modified probability range is signalled in a bitstream or parsed from the bitstream.

17. The method of claim 16, wherein the control syntax element is signalled or parsed in video level, sequence level, picture level, slice level, block level, or a combination thereof.

18. An apparatus of video coding, the apparatus comprising one or more electronic circuits or processors arranged to:
receive input data related to a current block, wherein the input data correspond to binarized bits corresponding to one or more syntax elements of the current block to be encoded using a CABAC encoder at a video encoder side, or the input data correspond to binary codewords for said one or more syntax elements of the current block generated by the CABAC encoder and to be decoded using a CABAC decoder at a video decoder side;
generate a modified probability range by clipping a probability range for context modelling of the CABAC encoder or the CABAC decoder, wherein the modified probability range excludes a probability value of 0; and
encode the current block using the CABAC encoder according to the modified probability range or decode the current block using the CABAC decoder according to the modified probability range.
